(19) United States
(12) Patent Application Publication
(10) Pub. No.: US 2025/0260406 A1
(43) Pub. Date: Aug. 14, 2025

(54) SINGLE-TANK QUADRATURE VOLTAGE-CONTROLLED OSCILLATOR (QVCO) AND METHOD OF OPERATION THEREOF

(71) Applicant: INDIAN INSTITUTE OF TECHNOLOGY ROPAR, Rupnagar (IN)

(72) Inventors: Mahendra SAKARE, Rupnagar (IN); Mayank Kumar SINGH, Rupnagar (IN); Hirensh MEHRA, Rupnagar (IN); Rajasekhar NAGULAPALLI, Oxford (GB)

(73) Assignee: INDIAN INSTITUTE OF TECHNOLOGY ROPAR, Rupnagar (IN)

(21) Appl. No.: 18/654,954

(22) Filed: May 3, 2024

(30) Foreign Application Priority Data
Feb. 12, 2024 (IN) 202411009384

(51) Int. Cl. H03L 7/099; H03B 5/12; H03B 27/00

(52) U.S. Cl. CPC H03L 7/099; H03B 5/1228; H03B 27/00

(57) ABSTRACT

A quadrature generation circuit comprises a VCO's two-phase outputs (inp and inn) are buffered through two inverters that generate the output of low pass filtered signals (p and n). Further low pass filtered signals (p and n) output is given to an arbitrary delay, to generate four delayed signals (p1d, p2d, n1d, and n2d). Phase averaging of (p and n2d) as well as (n and p2d) is performed to generate the output of (I and Ib) clocks respectively. In the same way, p1d and n1d signals output are given to two investors to perform phase averaging which generates the output of the Q and Qb clocks. The output clocks (I, Ib, Q, and Qb) have a 90-degree phase shift with each other.

### CROSS-REFERENCE TO RELATED APPLICATIONS AND PRIORITY

The present application claims benefit from Indian Patent Application No.: 202411009384 filed on 12 Feb. 2024 entirety of which is hereby incorporated by reference.

### TECHNICAL FIELD

The present subject matter described herein, in general, relates to a single-tank Quadrature voltage controller oscillator (QVCO). Particularly, the present subject matter relates to a single-tank Quadrature voltage controller oscillator (QVCO) based on the inverter coupling used for SERDES and wireless transceivers.

### BACKGROUND OF THE INVENTION

Quadrature clocks needed to facilitate interleaved operations in wireline and wireless transceivers. Quadrature clocks must meet specific quality criteria, such as minimal random and deterministic jitter, particularly in battery-operated handheld devices where power efficiency and silicon area usage are critical. Moreover, achieving a better Image Rejection Ratio (IRR) has become increasingly important as a modern way to quantify IQ phase error. When IQ clocks are separated by more than 90°, any resulting phase error can lead to spurious spurs in the system, often with minimal separation from the carrier, thus introducing deterministic jitter (DJ).

Traditionally, the generation of Quadrature clocks has involved methods like frequency dividers, Quadrature Voltage Controlled Oscillators (VCOs), or microwave couplers. However, these conventional techniques come with trade-offs involving high DC power consumption, high jitter, or a significant amount of silicon area. This invention introduces an innovative approach, the inverter-based poly-phase system (PPS), which leverages the phase interpolation method of linear time-invariant systems (LTI) to generate 90° phase-separated clock phases.

Hence to overcome the aforesaid drawbacks a single-tank Quadrature voltage controller oscillator (QVCO) is required.

### OBJECTS OF THE INVENTION

Main object of the present disclosure is to provide a single tank quadrature generation system comprising delay elements, summing invertors, and phase averaging circuit to provide 4 clocks having 90-degree phase shift with each other.

Another object of the present disclosure is to provide the Single-Tank Quadrature Voltage Controlled Oscillator (QVCO) to provide synchronized clock signals in systems like SERDES and wireless transceivers.

### SUMMARY OF THE INVENTION

Before the present system is described, it is to be understood that this application is not limited to the particular machine, device, or system, as there can be multiple possible embodiments that are not expressly illustrated in the present disclosures. It is also to be understood that the terminology used in the description is for the purpose of describing the particular versions or embodiments only, and is not intended to limit the scope of the present application. This summary is provided to introduce aspects related to the single-tank Quadrature voltage controller oscillator (QVCO), and the aspects are further elaborated below in the detailed description. This summary is not intended to identify essential features of the proposed subject matter nor is it intended for use in determining or limiting the scope of the proposed subject matter.

In an embodiment, the present disclosure provides a single-tank quadrature voltage-controlled oscillator (QVCO), comprising a poly-phase system (PPS) configured to generate two phase signals, and provide said signals to buffers configured to generate low pass filtered signals p, n as buffered outputs, at least an arbitrary delay elements configured for generating four signals P1d and P2d, N1d and N2d signals from the p, and n low pass filtered signals, respectively, at least a current summing inverter(s) configured to employ a current summing technique for phase averaging between P and N2d signals, and N and P2d signal to establish a 90-degree phase difference from the N2d and P2d signals which generate an output of I and Ib signals, and at least a phase averaging inverter(s) configured to perform a phase averaging of P1d and N1d signal to generate an output of Q and Qb signals, wherein, I signal and Q signal have a 90-degree phase shift with each other.

In an embodiment, the present disclosure provides the delay elements comprises a delay cell consisting of cascaded inverters with a delay-tuning capacitor, positioned between the buffer and the current summing inverters.

In an embodiment, the present disclosure provides the delay elements comprises either the cascaded inverters.

In an embodiment, the present disclosure provides the phase averaging inverter comprises a current summing inverters that connect two inverters at the input and shorting the output.

In an embodiment, the present disclosure provides the current summing inverter(s) comprises a first summing inverter configured to employ the current summing technique for phase averaging between P and N2d signals; and a second summing inverter configured to employ the current summing technique for phase averaging between N and P2d signal.

In an embodiment, the present disclosure provides the poly-phase system (PPS) comprises a voltage controlled oscillator configured to generate two phase outputs, namely “Iₙₚ” and “Iₙₘ”.

In yet another embodiment, the present disclosure provides a method for generating quadrature clock signals in a single-tank quadrature voltage-controlled oscillator, comprising the steps of buffering two-phase outputs generated from a poly-phase system through inverters to generate low pass filtered signals P, and N as buffered outputs; generating four signals P1d and P2d, N1d and N2d signals from the p, and n low pass filtered signals by introducing an arbitrary delay via a delay elements; employing, by a current summing inverter, an current summing technique for phase averaging between P and N2d signals, and N and P2d signal to establish a 90-degree phase difference from the N2d and P2d signals which generate an output of I and Ib signals, and performing phase averaging, by a phase averaging inverter, of P1d and N1d signal to generate an output of Q and Qb signals; wherein, I signal and Q signal have a 90-degree phase shift with each other.

In an embodiment, the present disclosure provides the phase averaging step involves configuring current summing inverters to achieve a weighted summation of the input phase for generating I, Q, Ib, and Qb signals with a 90° phase shift.

### BRIEF DESCRIPTION OF DRAWING

The foregoing summary, as well as the following detailed description of embodiments, is better understood when read in conjunction with the appended drawings. For the purpose of illustrating the disclosure, there is shown in the present document example constructions of the disclosure, however, the disclosure is not limited to the specific methods and device disclosed in the document and the drawing. The detailed description is described with reference to the following accompanying figures.

FIG. 1: illustrates the prior art consisting of a circuit diagram of the conventional Quadrature Voltage Controlled Oscillator (QVCO) for generating IQ clocks.

FIG. 2: illustrates the prior art consisting of IQ generation system centered around a frequency divider of two D-latches connected in a back-to-back negative feedback configuration.

FIG. 3: illustrates the prior art consisting of the Poly Phase Filter (PPF) comprising four sets of RC high-pass filters.

FIG. 4: illustrates the Single-tank Quadrature generation system configured with the inverters, in accordance with an embodiment of the present subject matter.

FIG. 5: illustrates the proposed exploded view of a Delay elements comprising a pair of inverters and capacitor, in accordance with an embodiment of the present subject matter.

FIG. 6: illustrates the proposed exploded view of the circuit diagram of the inverter, in accordance with an embodiment of the present subject matter.

FIG. 7: illustrates the Vector representation of the working of the quadrature generation system.

FIG. 8: illustrates the simulation response for Phase error versus supply voltage for different corners.

FIG. 9: illustrates the simulation response for Random Jitter (RJ) between the proposed circuit and the divider-based approach across various PVT corners.

The figures depict various embodiments of the present disclosure for purposes of illustration only. One skilled in the art will readily recognize from the following discussion that alternative embodiments of the structures illustrated herein may be employed without departing from the principles of the disclosure described herein.

### DETAILED DESCRIPTION OF THE INVENTION

Some embodiments of this disclosure, illustrating all its features, will now be discussed in detail. The words “comprising”, “having”, and “including,” and other forms thereof, are intended to be equivalent in meaning and be open ended in that an item or items following any one of these words is not meant to be an exhaustive listing of such item or items, or meant to be limited to only the listed item or items. It must also be noted that as used herein and in the appended claims, the singular forms “a,” “an,” and “the” include plural references unless the context clearly dictates otherwise. Although any devices and methods similar or equivalent to those described herein can be used in the practice or testing of embodiments of the present disclosure, the exemplary, devices and methods are now described. The disclosed embodiments are merely exemplary of the disclosure, which may be embodied in various forms.

Various modifications to the embodiment will be readily apparent to those skilled in the art and the generic principles herein may be applied to other embodiments. However, one of ordinary skill in the art will readily recognize that the present disclosure is not intended to be limited to the embodiments illustrated, but is to be accorded the widest scope consistent with the principles and features described herein.

Following is a list of elements and reference numerals used to explain various embodiments of the present subject matter.

| Reference | |
|---|---|
| Numeral | Element Description |
| 100 | Quadrature generation system |
| 101 | VCO's two-phase outputs (inp and inn) |
| 102 | Low pass filtered signals p, n |
| 103 | Delayed signal (p1d) |
| 104 | Delayed signal (p2d) |
| 105 | Delayed signal (n1d) |
| 106 | Delayed signal (n2d) |
| 107 | Delay elements |
| 108 | Inverter |
| 109 | Quadrature clocks (I, Ib, Q, and Qb) |
| 700 | Vector representation of the working of the quadrature |
| | generation system |

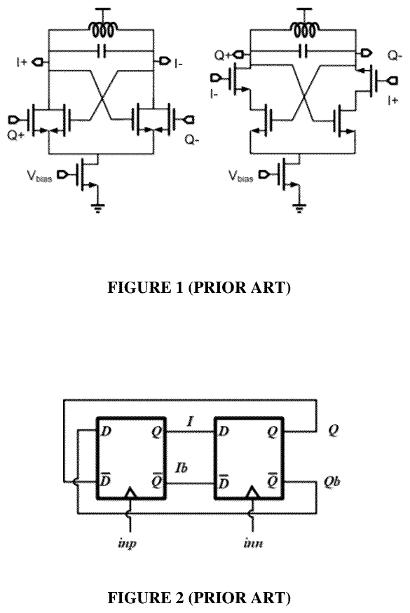

FIG. 1 illustrates a prior art showing a simplified diagram of a Quadrature Voltage Controlled Oscillator (QVCO) for generating IQ clocks. This diagram consists of two identical VCOs coupled to each other with out-of-phase signals. An I signal is injected into the VCO responsible for generating the Q signal and vice versa. Wherein this method effectively produces precise quadrature clocks, it has certain drawbacks. Like, it incurs a double power consumption and requires twice the physical area due to using two identical tanks.

Additionally, a significant concern is the presence of a phase ambiguity issue. In certain instances, the I signal may lead the Q signal, while in other situations, the Q signal may lead the I signal. Such phase ambiguity poses challenges, particularly in SERDES applications.

FIG. 2 illustrates a prior art showing a simplified diagram of another prevalent IQ generation system centered around a frequency divider of two D-latches connected in a back-to-back negative feedback configuration. Wherein the “inp” and “inn” signals are driven by the Voltage Controlled Oscillator (VCO), there is a significant drawback to this method. To generate Quadrature clocks at the desired “f0” frequency, the VCO must be redesigned to operate at twice the “2f” frequency. The requirement for producing a clock at a doubled frequency can be challenging in terms of design complexity and results in less-than-ideal jitter performance. The distribution of such high-frequency clocks poses a considerable challenge, further introducing jitter.

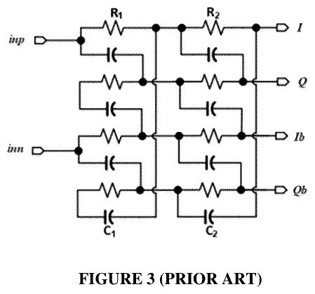

FIG. 3 illustrates a prior art showing a simplified diagram of the Poly Phase Filter (PPF), comprising four sets of RC high-pass filters, with multiple stages employed to enhance Amplitude Modulation (AM) performance. This circuit's fundamental operating principle lies in the inherent 45-degree phase difference between the input and output of a first-order RC filter, which accumulates to form quadrature phase differences over two stages. The key advantage of this circuit is its low power consumption due to its passive nature, contributing to low jitter. However, it does come with a limitation i.e., its bandwidth is relatively narrow, requiring a robust, power-hungry VCO driver to function effectively,

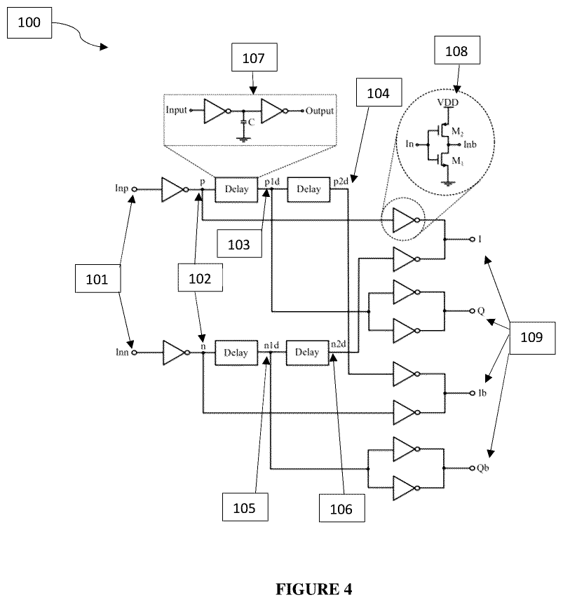

FIG. 4 illustrates a circuit diagram of a Quadrature generation system (100) configured with the inverters (108). A circuit for a single-tank quadrature voltage-controlled oscillator (QVCO) comprises a VCO's two-phase outputs namely (inp and inn) (101) are buffered through two inverters that generate the output of low pass filtered signals (p and n) (102), wherein the inverter circuit (108) comprises an nMOS (M1) transistor for current discharge, and pMOS (M2) for the current charge, wherein the gate terminal of NMOS (M1) and PMOS (M2) transistors are shorted which receive an input signal (In), and the source terminal of NMOS (M1) and drain terminal of PMOS (M2) transistors are shorted that generates output signal (Ib). Further low pass filtered signals (p and n) (102) output is given to an arbitrary delay, which generates four signals (p1d, n1d, p2dand n2d) (103) (104) (105) (106), wherein p1d (103) and p2d (104) represent delayed versions of the (inp) signal (101), and (n1d) (105) and (n2d) (106) represent delayed versions of the “inn” signal (101). The arbitrary delays are designed by cascading two inverters with a delay-tuning capacitor positioned between the intermediate terminals of the two inverters as shown in figure no 5. Further, the phase averaging of (p (101) and n2d (106)) as well as (n (101) and p2d (104)) is performed to establish a 90-degree phase difference from the (p1d (103) and p2d (104)) signals which generate the output of (I and Ib) clocks respectively, wherein the phase averaging is executed by configuring current summing inverters (108) that connect two inverters (108) at the input and shorting the output as shown in FIG. 4. In the same way, p1d (103) and n1d (105) signals output are given to two investors to perform phase averaging which generates the output of the Q and Qb clocks. The output clocks I, Ib, Q, and Qb (109) have a 90-degree phase shift with each other.

Adjusting the inverter (108) drive strength achieves a weighted summation of the input phase. This approach primarily adopts a CMOS design methodology, although Current Mode Logic (CML) can be a viable alternative, especially in scenarios where high power supply rejection performance is imperative. However, it is essential to note that this proposal remains versatile, as it is unrelated to CMOS or CML, the fundamental concept remains the same as long as the signals are configured appropriately to achieve I and Q clocks.

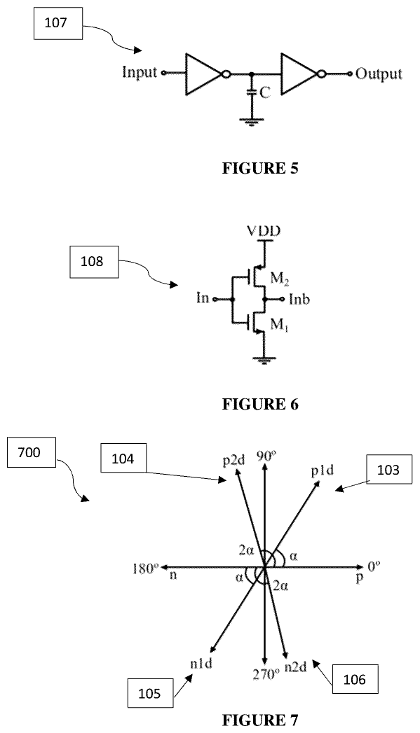

FIG. 5 illustrates the exploded view of a delay elements (107) used in a quadrature generation system. The Dell elements is designed by cascading two inverters with a delay-tuning capacitor positioned between the intermediate terminals of the inverter circuit (108). The capacitor used in the delay elements (107) has a range in Femto (10⁻¹⁵) farads. This proposed invention does not hinge on specific delay elements (107) design, alternatives such as current-starved inverters or sample-and-hold circuits can also be employed.

FIG. 6 illustrates the exploded view of the inverter (108) used in a quadrature generation system. The inverter circuit (108) comprises an nMOS transistor (M1) for the current discharge, and a pMOS transistor (M2) for the current charge, wherein the gate terminal of NMOS (M1) and PMOS (M2) transistors are shorted which receive an input signal (In), and the source terminal of NMOS (M1) and drain terminal of PMOS (M2) transistors are shorted that generates an output signal (Ib).

FIG. 7 illustrates the Vector representation (700) of the working of the quadrature generation system. Wherein, low pass filtered signals p and n (102) are the sinusoidal clock signals coming from the VCO and represented in below equations.

$$p = A \cdot sin ( θ )$$

$$n = A \cdot sin ( θ - 180 ° )$$

Wherein A is the amplitude of the signal and θ is the phase of the signal. The delayed version (delayed by one delay element ∝ and two delay elements 2∝) of the low pass filtered signals p and n (102) are represented by (p1d (103), p2d (104)) and (n1d (105), n2d (106)).

$$p 1 d = A sin ( θ - ∝ )$$

$$p 2 d = A sin ( θ - 2 ∝ )$$

$$n 1 d = A sin ( θ - 180 ° - ∝ )$$

$$n 2 d = A sin ( θ - 180 ° - 2 ∝ )$$

For phase averaging of the signals, the interpolation is performed between signals (p (101) & n2d (106)) and (n (101) & p2d (104)). By interpolating p (102) and n2d (106), one can get I=Asin (θ+90°−∝), which makes the phase difference between I & p1d (103) to 90°, meaning they are in quadrature. If one interpolates n (101) & p2d (104), it will get Ib. Similarly, Q and Qb can be generated. All these signals will be in quadrature. Accordingly, Output clocks (I, Ib, Q, Qb) (109) has 90-degree phase shift with each other.

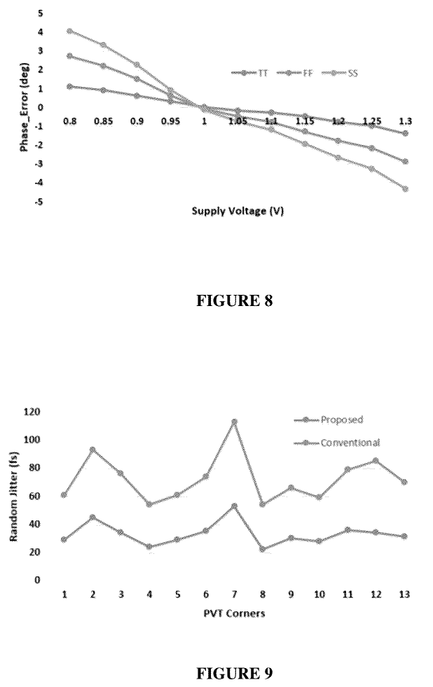

FIG. 8 illustrates the simulation graph showing the phase error variation across different Process, Voltage, and Temperature (PVT) corners, namely TT (Typical-Typical), FF (Fast-Fast), and SS (Slow-Slow). The phase error spans within the range of +/−40 as the supply voltage is adjusted from 0.8 to 1.3 V, covering a substantial voltage spectrum. These results indicate that there is no necessity for integrating a bulky, space-consuming regulator to manage the supply voltage.

FIG. 9 illustrates the simulation graph showing a comparison of Random Jitter (RJ) between the proposed circuit as shown in FIG. 4 and the divider-based circuit as shown in FIG. 2 across various PVT corners. The quadrature generation system (400) exhibits a maximum RJ of 53 femtoseconds (fs), while the conventional technique records 110 fs. The most challenging scenario occurs at the slow corner, with low voltage and high temperature, primarily due to the clock signals slower edge rates in this configuration. These findings highlight the superiority of the proposed circuit in terms of jitter performance and robustness across diverse PVT conditions.

In some embodiments, the single-tank quadrature voltage-controlled oscillator (QVCO) is proposed, which consists of a poly-phase system (PPS) for quadrature phase generation.

In some embodiments, the PPS consists of the inverter (for one delay) and delay elements (for two delays) for shifting the phases to generate p1d, p2d, n1d, and n2d signals (103) (104) (105) (106) from low pass filtered signals (p and n) (102).

In some embodiments, the phase averaging of the signals is done between (p (101), n2d (106)) and (n (101), p2d (104)) signals to generate the I, Q, Ib, and Qb (109) signals with a phase shift of 90-degree.

In some embodiments, the key advantage of this quadrature generation system (100) over conventional methods lies in its independence from a 2× input clock frequency requirement, offering a broader input frequency range comparable to divider-based IQ generation systems.

In some embodiments, the phase error introduced by this quadrature generation system (100) is significantly improved because of the phase averaging technique.

In some embodiments, the quadrature generation system (100) provides an efficient and effective means to generate Quadrature clock signals, eliminating the shortcomings of existing methods.

In some embodiments, the quadrature generation system (100) enhances the performance of SERDES and wireless transceiver systems, optimizing power efficiency and clock signal quality.

### Equivalents

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present.

Although implementations for the Single-tank Quadrature voltage controller oscillator (QVCO) based on the inverter coupling have been described in language specific to structural features and/or methods, it is to be understood that the appended claims are not necessarily limited to the specific features described. Rather, the specific features are disclosed as examples of implementation for the Single-tank Quadrature voltage controller oscillator (QVCO) based on the inverter coupling.

1. A single-tank quadrature voltage-controlled oscillator (QVCO), comprising
a poly-phase system (PPS) configured to generate two phase signals, and provide said signals to buffers configured to generate low pass filtered signals p, n as buffered outputs;
at least an arbitrary delay elements configured for generating four signals P1d and P2d, N1d and N2d signals from the p, and n low pass filtered signals, respectively;
at least a current summing inverter(s) configured to employ a current summing technique for phase averaging between P and N2d signals, and N and P2d signal to establish a 90-degree phase difference from the N2d and P2d signals which generate an output of I and Ib signals; and
at least a phase averaging inverter(s) configured to perform a phase averaging of P1d and N1d signal to generate an output of Q and Qb signals;
wherein, I signal and Q signal have a 90-degree phase shift with each other.

2. The oscillator as claimed in claim 1, wherein the delay elements comprises a delay cell consisting of cascaded inverters with a delay-tuning capacitor, positioned between the buffer and the current summing inverters.

3. The oscillator as claimed in claim 1, wherein the delay elements comprises either the cascaded inverters.

4. The oscillator as claimed in claim 1, wherein the phase averaging inverter comprises a current summing inverters that connect two inverters at the input and shorting the output.

5. The oscillator as claimed in claim 1, wherein the current summing inverter(s) comprises a first summing inverter configured to employ the current summing technique for phase averaging between P and N2d signals; and
a second summing inverter configured to employ the current summing technique for phase averaging between N and P2d signal.

6. The oscillator as claimed in claim 1, wherein the poly-phase system (PPS) comprises a voltage controlled oscillator configured to generate two phase outputs, namely “Imp” and “Inn”.

7. A method for generating quadrature clock signals in a single-tank quadrature voltage-controlled oscillator, comprising the steps of
buffering two-phase outputs generated from a poly-phase system through inverters to generate low pass filtered signals P, and N as buffered outputs;
generating four signals P1d and P2d, N1d and N2d signals from the p, and n low pass filtered signals by introducing an arbitrary delay via delay elements;
employing, by a current summing inverter, an current summing technique for phase averaging between P and N2d signals, and N and P2d signal to establish a 90-degree phase difference from the N2d and P2d signals which generate an output of I and Ib signals, and
performing phase averaging, by a phase averaging inverter, of P1d and N1d signal to generate an output of Q and Qb signals;
wherein, I signal and Q signal have a 90-degree phase shift with each other.

8. The method as claimed in claim 7, wherein the phase averaging step involves configuring current summing inverters to achieve a weighted summation of the input phase for generating I, Q, Ib, and Qb signals with a 90° phase shift.
